(19) United States
(12) Patent Application Publication
(10) Pub. No.: US 2024/0339787 A1
(43) Pub. Date: Oct. 10, 2024

(54) BOARD CONNECTOR AND DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Toshikazu SUZUKI, Osaka (JP); Toshifumi ICHIO, Osaka (JP); Daisuke ITO, Osaka (JP); Kazuki HIRAMATSU, Mie (JP); Taiga KADOYAMA, Mie (JP)

(21) Appl. No.: 18/579,410

(22) PCT Filed: Jun. 27, 2022
(86) PCT No.: PCT/JP2022/025495

§ 371 Date: Jan. 15, 2024

(30) Foreign Application Priority Data
Jul. 16, 2021 (JP) 2021-117616

(51) Int. Cl. H01R 13/6582; H01R 12/70; H01R 13/502; H01R 13/655; H05K 9/00

(52) U.S. Cl. CPC H01R 13/6582; H01R 12/707; H01R 13/5025; H01R 13/655; H05K 9/0049

(57) ABSTRACT

A board connector of the present disclosure is to be mounted on a circuit board and provided with a housing including a receptacle open forward and a rear wall provided on a side opposite to a front end part where the receptacle is open, an outer conductor fixed to the housing through the rear wall, an insulating dielectric disposed inside the outer conductor, an inner conductor disposed inside the dielectric, and a ground spring to be connected to the outer conductor. The receptacle includes a first wall to be disposed on a side opposite to the circuit board, a second wall to be disposed on the side of the circuit board and a third wall coupling the first wall and the second wall.

### TECHNICAL FIELD

The present disclosure relates to a board connector and a device.

### BACKGROUND

Conventionally, a connector described in Japanese Patent Laid-Open Publication No. 2016-207411 (Patent Document 1 below) is known as a connector to be mounted on a circuit board. This connector includes electrically conductive signal terminals, an insulating housing for holding the signal terminals, an electrically conductive shell for covering the housing, an electrically conductive upper-stage ground terminal disposed above the signal terminals and held in the housing, and an electrically conductive lower-stage ground terminal disposed below the signal terminal and held in the housing. The upper-stage ground terminal includes a contact portion to be brought into contact with a back surface side of the shell.

The shell is a member for shielding the signal terminals of the connector from external electrical noise and establishing ground connection of the upper-stage ground terminal. The shell has a box shape with open front and lower surfaces. A part of the upper surface of the shell is cut and bent outward and serves as a shell-side ground connecting portion to be connected to a ground terminal of a unit enclosure for accommodating the connector. The back surface of the shell has a contact surface to be brought into contact with the contact portion of the upper-stage ground terminal.

The upper-stage ground terminal has a function as a ground terminal to be ground-connected by being connected to female ground of a mating connector. The contact portion of the upper-stage ground terminal is in contact with the contact surface of the shell, and the shell-side ground connecting portion is in contact with the ground terminal of the unit enclosure. In this way, a ground line to the ground terminal of the unit enclosure is configured via the female ground, the upper-stage ground terminal, the shell and the shell-side ground connecting portion of the shell.

### PRIOR ART DOCUMENT

### Patent Document

Patent Document 1: JP 2016-207411 A

### SUMMARY OF THE INVENTION

### Problems to be Solved

In the above connector, since the shell-side ground connecting portion is provided only on the upper surface of the shell, communication performance is deteriorated under the influence of noise in the case of high-speed communication.

A technique disclosed in this specification was completed on the basis of the above situation and aims to provide a board connector and a device capable of reducing noise.

### Means to Solve the Problem

The present disclosure is directed to a board connector to be mounted on a circuit board, the board connector being provided with a housing including a receptacle open forward and a rear wall provided on a side opposite to a front end part where the receptacle is open, an outer conductor fixed to the housing through the rear wall, an insulating dielectric disposed inside the outer conductor, an inner conductor disposed inside the dielectric, and a ground spring to be connected to the outer conductor, the receptacle including a first wall to be disposed on a side opposite to the circuit board, a second wall to be disposed on the circuit board side and a third wall coupling the first wall and the second wall, and the ground spring including a first enclosure connecting portion disposed on an outer surface side of the first wall and a second enclosure connecting portion disposed on an outer surface side of each or either one of the second wall and the third wall.

### Effect of the Invention

According to the present disclosure, it is possible to provide a board connector and a device capable of reducing noise.

### BRIEF DESCRIPTION OF THE DRAWINGS

FIG. 1 is a perspective view showing a board connector of a first embodiment.

FIG. 2 is an exploded perspective view of a device.

FIG. 3 is a front view of the board connector.

FIG. 4 is a side view of the board connector.

FIG. 5 is a perspective view showing the board connector before an outer conductor is press-fit into a housing.

FIG. 6 is a section along A-A of FIG. 3.

FIG. 7 is a section along B-B of FIG. 3.

FIG. 8 is a section along C-C of FIG. 4.

FIG. 9 is a horizontal section along D-D of FIG. 4 of the device showing a state where the outer conductor is electrically connected to an enclosure via a ground spring in the board connector.

FIG. 10 is a longitudinal section of the device showing the state where the outer conductor is electrically connected to the enclosure via the ground spring.

FIG. 11 is a perspective view showing a board connector of a second embodiment.

FIG. 12 is a perspective view showing a board connector of a third embodiment.

### DETAILED DESCRIPTION TO EXECUTE THE INVENTION

### Description of Embodiments of Present Disclosure

First, embodiments of the present disclosure are listed and described.

(1) The board connector of the present disclosure is to be mounted on a circuit board, and provided with a housing including a receptacle open forward and a rear wall provided on a side opposite to a front end part where the receptacle is open, an outer conductor fixed to the housing through the rear wall, an insulating dielectric disposed inside the outer conductor, an inner conductor disposed inside the dielectric, and a ground spring to be connected to the outer conductor, the receptacle including a first wall to be disposed on a side opposite to the circuit board, a second wall to be disposed on the circuit board side and a third wall coupling the first wall and the second wall, and the ground spring including a first enclosure connecting portion disposed on an outer surface side of the first wall and a second enclosure connecting portion disposed on an outer surface side of each or either one of the second wall and the third wall.

A device of the present disclosure is provided with the board connector, a circuit board having the board connector mounted thereon, and an enclosure made of metal, the circuit board being accommodated inside the enclosure, the enclosure being electrically connected to the outer conductor via the ground spring, the enclosure including a first spring receiving portion to be connected to the first enclosure connecting portion and a second spring receiving portion to be connected to the second enclosure connecting portion.

Since the ground spring includes the first and second enclosure connecting portions, the ground spring can be shield-connected to the enclosure at least at two positions and noise can be reduced. Further, since the outer conductor and the enclosure made of metal can be electrically connected via the ground spring, a connected state is stable and shielding performance can be improved.

(2) Preferably, the ground spring includes a mounting body portion to be disposed along an outer surface of the rear wall, the first enclosure connecting portion includes a plurality of first connection springs projecting forward from a front edge of the mounting body portion, and the second enclosure connecting portion includes a plurality of second connection springs projecting forward from the front edge of the mounting body portion.

Since the ground spring includes the plurality of first connection springs and the plurality of second connection springs, the ground spring can be shield-connected to the enclosure at multiple contact points and shielding performance can be further improved.

(3) Preferably, the mounting body portion has a rectangular tube shape and includes a first mounting wall corresponding to the first wall, a second mounting wall corresponding to the second wall and third mounting walls corresponding to the third wall, a pair of the third mounting walls are provided to face each other in a direction orthogonal to a facing direction of the first mounting wall and the second mounting wall, and the second enclosure connecting portions are disposed on both the second mounting wall and the pair of third mounting walls.

Since the ground spring includes one first enclosure connecting portion and three second enclosure connecting portions, the ground spring can be shield-connected to the enclosure at least at four positions and noise can be further reduced.

(4) Preferably, the outer conductor includes a flange to be disposed along the rear wall of the housing, and the first mounting wall includes a holding spring to be brought into resilient contact with the flange from behind and the pair of third mounting walls include a pair of clamping pieces for clamping the flange together with the holding spring.

Since the flange can be clamped by the holding spring and the pair of clamping pieces, a connected state of the ground spring to the flange is stable.

(5) Preferably, a pair of the second enclosure connecting portions are provided on the pair of third mounting walls, and the holding spring is provided on a rear edge of the first mounting wall and the pair of clamping pieces are provided on rear edges of the pair of third mounting walls.

Since the holding spring is provided on the rear edge of the first mounting wall, the holding spring and the first enclosure connecting portion can be connected by a shortest distance. Further, since the pair of clamping pieces are provided on the rear edges of the pair of third mounting walls, the pair of clamping pieces and a pair of the second enclosure connecting portions can be connected by a shortest distance.

### Details of First Embodiment of Present Disclosure

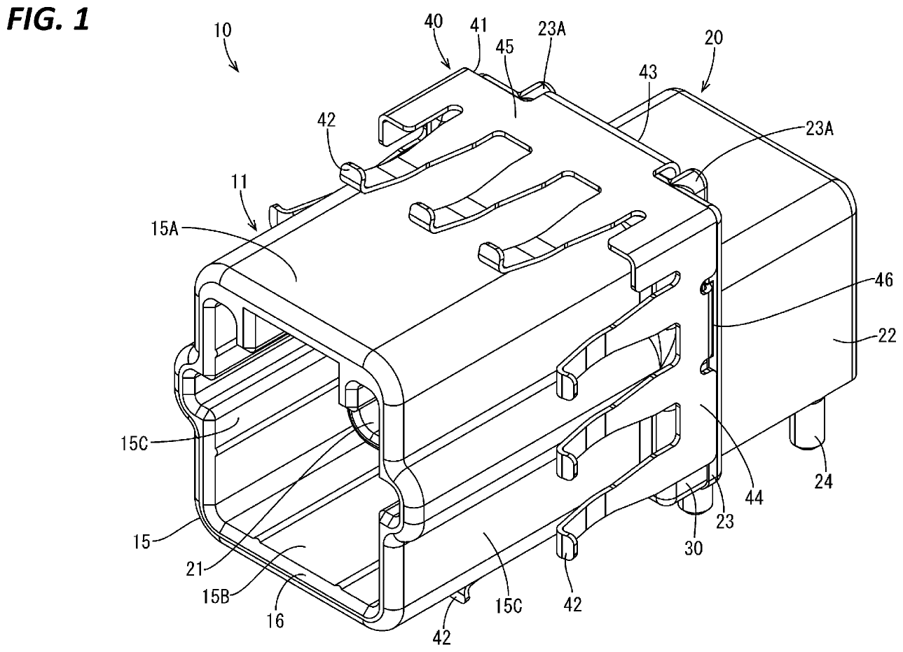

Specific examples of a board connector 10 and a device 60 of the present disclosure are described with reference to FIGS. 1 to 10. Note that the present disclosure is not limited to these illustrations, but is represented by claims and intended to include all changes in the scope of claims and in the meaning and scope of equivalents.

### [Overall Structures of Board Connector and Device]

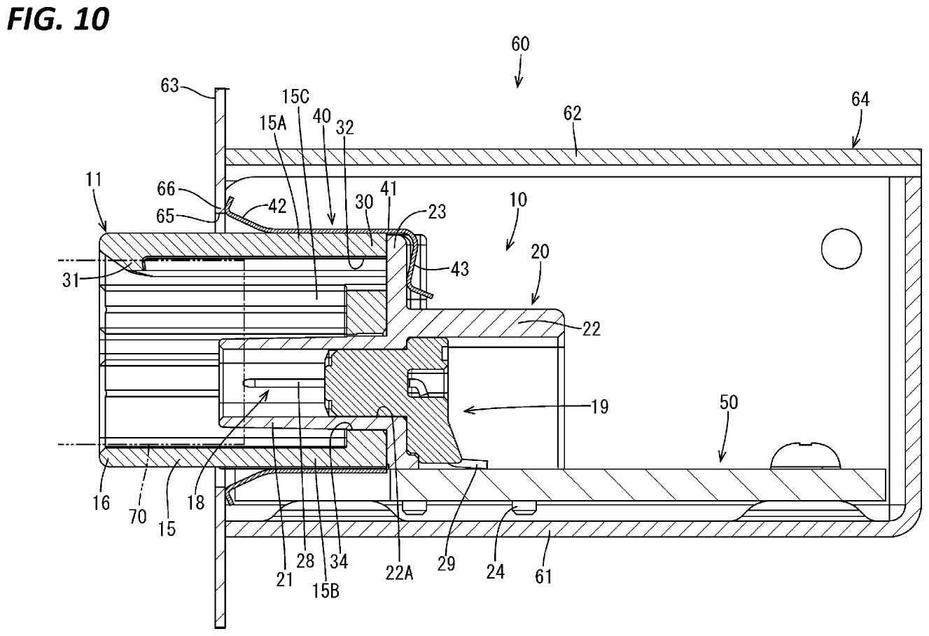

The board connector 10 according to this embodiment is mounted on a circuit board 50 accommodated inside the device 60 as shown in FIG. 10. A front-rear direction is based on a lateral direction in FIG. 10 with a left side set as a front side, and a vertical direction is based on a vertical direction in FIG. 10. Further, for a plurality of identical members, only some members may be denoted by a reference sign and the other members may not be denoted by the reference sign.

### [Device]

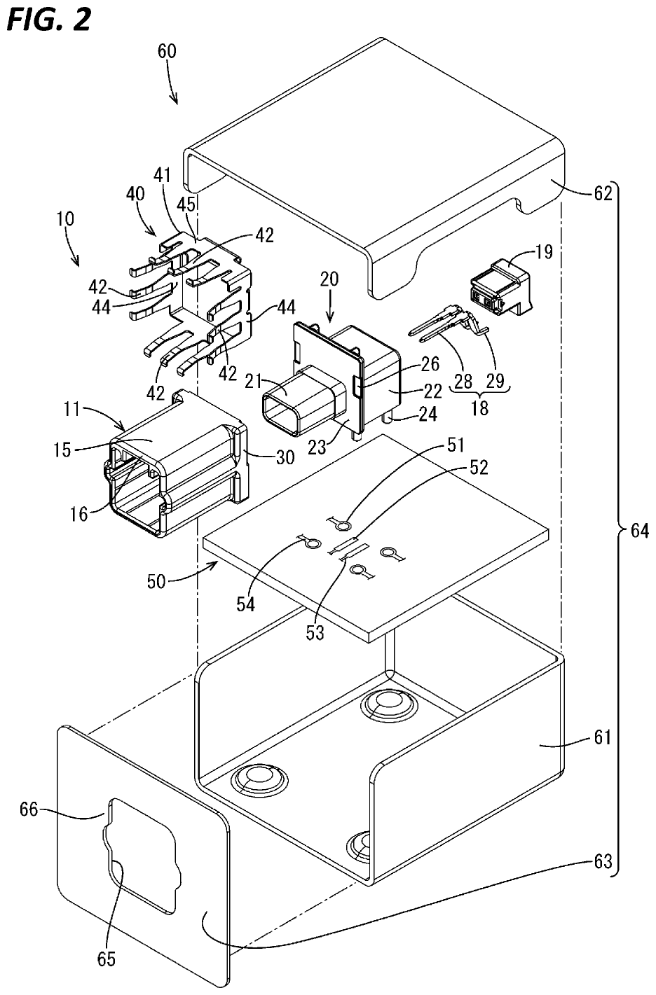

As shown in FIG. 2, the device 60 is provided with a lower case 61 open upward and forward, an upper case 62 for closing an upper opening of the lower case 61 by being assembled with the lower case 61 from above, and a front panel 63 for closing a front opening of the lower case 61 by being assembled with the lower case 61 from front. The lower case 61, the upper case 62 and the front panel 63 are made of electrically conductive metal. The lower case 61, the upper case 62 and the front panel 63 are integrally assembled by a known method such as screwing or locking structures, whereby an enclosure 64 is formed. The enclosure 64 has a rectangular parallelepiped shape as a whole.

The front panel 63 is provided with a connector insertion hole 65, through which a part of the board connector 10 is inserted. A front wall 66 constituting the connector insertion hole 65 is a wall for shield connection to be resiliently contacted by a ground spring 40 to be described later from behind. The front wall 66 corresponds to a “spring receiving portion” described in claims.

The circuit board 50 is accommodated in the enclosure 64. The circuit board 50 is fixed to the enclosure 64 by a known method such as screwing. As shown in FIG. 2, the circuit board 50 is formed with signal electrically conductive paths 53, in which signals are transmitted, and ground electrically conductive paths 54 by etching a copper foil by known printed wiring technique. A plurality of (four in this embodiment) outer conductor through holes 51 and a plurality of (two in this embodiment) inner conductor lands 52 are formed at positions near a front end part of the circuit board 50. An electrically conductive path (not shown) is formed on the inner peripheral surface of the outer conductor through hole 51 by through hole copper plating or the like.

The electrically conductive path formed on the inner peripheral surface of the outer conductor through hole 51 is electrically connected to the ground electrically conductive path 54. Further, an electrically conductive path formed on the surface of the inner conductor land 52 constitutes a part of the signal electrically conductive path 53. Unillustrated electronic components are connected to the signal electrically conductive paths 53 and the ground electrically conductive paths 54 of the circuit board 50 by a known method such as soldering.

### [Board Connector]

As shown in FIG. 10, the board connector 10 includes a housing 11 to be mounted on the circuit board 50, an outer conductor 20 to be attached to the housing 11, a dielectric 19 to be accommodated inside the outer conductor 20, inner conductors 18 to be accommodated inside the dielectric 19 and the ground spring 40 to be connected to the outer conductor 20.

### [Housing]

The housing 11 is formed by injection-molding an insulating synthetic resin. The housing 11 includes a receptacle 15, which is open forward and into which a mating connector 70 is fit, and a rear wall 30 provided on a side opposite to a front end side (opening end part) 16 where the receptacle 15 is open. A lock portion 31 projecting downward is provided on the front end edge (opening end part) of the inner wall of the receptacle 15. The lock portion 31 is locked to a lock arm (not shown) provided on the mating connector 70, thereby holding the mating connector 70 in a state fit in the receptacle 15.

As shown in FIGS. 1 and 10, the receptacle 15 includes a first wall 15A to be disposed on a side opposite to the circuit board 50, a second wall 15B to be disposed on the side of the circuit board 50, and a pair of third walls 15C coupling the first and second walls 15A, 15B. The pair of third walls 15C are disposed to face each other in a direction (lateral direction) orthogonal to a facing direction of the first and second walls 15A, 15B.

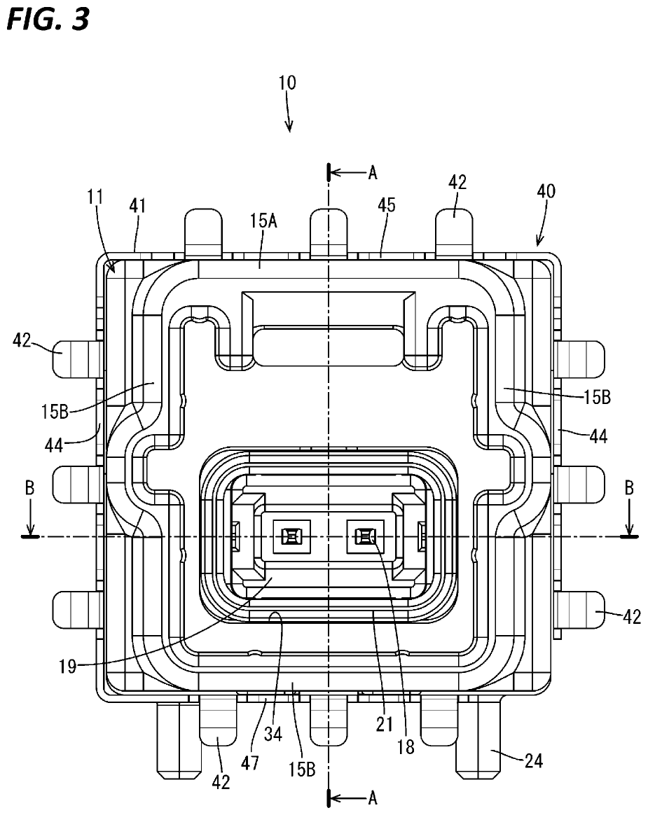

The rear wall 30 is located on a rear end part of the housing 11. As shown in FIG. 2, the rear wall 30 is larger than the first and second walls 15A, 15B of the receptacle 15 in the lateral direction and has the same size as the third walls 15C in the vertical direction. As shown in FIG. 10, a mold removal hole 32 for forming the lock portion 31 in injection-molding the housing 11 is formed to penetrate in the front-rear direction at a position of the rear wall 30 behind the lock portion 31. An outer conductor mounting hole 34, through which the outer conductor 20 is inserted, is formed to penetrate in the front-rear direction below the mold removal hole 32 in the rear wall 30. As shown in FIG. 3, the inner peripheral surface of the outer conductor mounting hole 34 has a rectangular shape with rounded corners.

### [Outer Conductor]

As shown in FIG. 2, the outer conductor 20 is made of electrically conductive metal. An arbitrary metal such as copper, copper alloy, zinc, aluminum or aluminum alloy can be appropriately selected as a metal for constituting the outer conductor 20. The outer conductor 20 is formed by a known method such as casting, die casting or cutting. The outer conductor 20 is brought into electrical contact with a mating outer conductor (not shown) accommodated in the mating connector 70.

The outer conductor 20 includes a tube portion 21 extending in the front-rear direction and having a tubular shape, a dielectric surrounding portion 22 extending rearward from the rear end edge of the tube portion 21 and a flange 23 projecting in a direction intersecting the front-rear direction on a boundary part between the tube portion 21 and the dielectric surrounding portion 22.

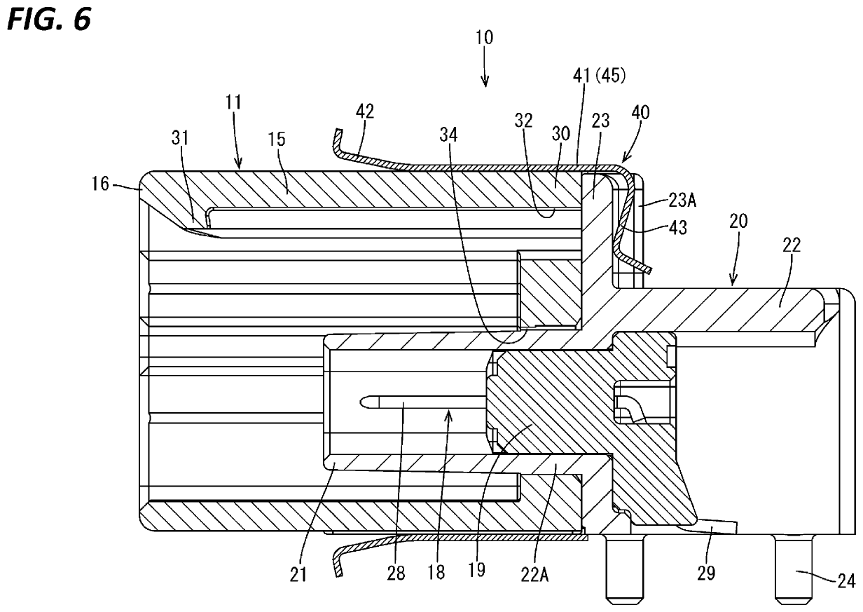

As shown in FIG. 6, a dielectric holding portion 22A for holding the dielectric 19 inside is provided to be open in the front-rear direction in the boundary part between the tube portion 21 and the dielectric surrounding portion 22.

As shown in FIG. 3, the outer peripheral surface of the tube portion 21 has a rectangular shape with rounded corners when viewed from front. The outer peripheral shape of the tube portion 21 is set to have substantially the same size as the inner peripheral shape of the outer conductor mounting hole 34 of the rear wall 30. In this way, the tube portion 21 can be press-fit into the outer conductor mounting hole 34 from behind. The housing 11 is fixed to the outer conductor 20 by the tube portion 21 being press-fit into the outer conductor mounting hole 34.

As shown in FIG. 6, the dielectric surrounding portion 22 has a gate shape open downward. The dielectric 19 is accommodated inside the dielectric surrounding portion 22 while being surrounded on upper, left and right sides by the dielectric surrounding portion 22.

As shown in FIG. 2, a plurality of (four in this embodiment) cylindrical board connecting portions 24 projecting downward are provided on a lower end part of the dielectric surrounding portion 22. The board connecting portion 24 is inserted into the outer conductor through hole 51 of the circuit board 50 and connected to the conductive path formed on the inner surface of the outer conductor through hole 51 by a known method such as soldering. In this way, the outer conductor 20 is electrically connected to the ground electrically conductive paths 54 formed in the circuit board 50.

As shown in FIG. 6, with the tube portion 21 press-fit to the inner peripheral wall of the outer conductor mounting hole 34, the flange 23 is in contact with the rear surface of the rear wall 30 from behind. In this way, the mold removal hole 32 of the rear wall 30 is closed from behind by the flange 23.

### [Dielectric]

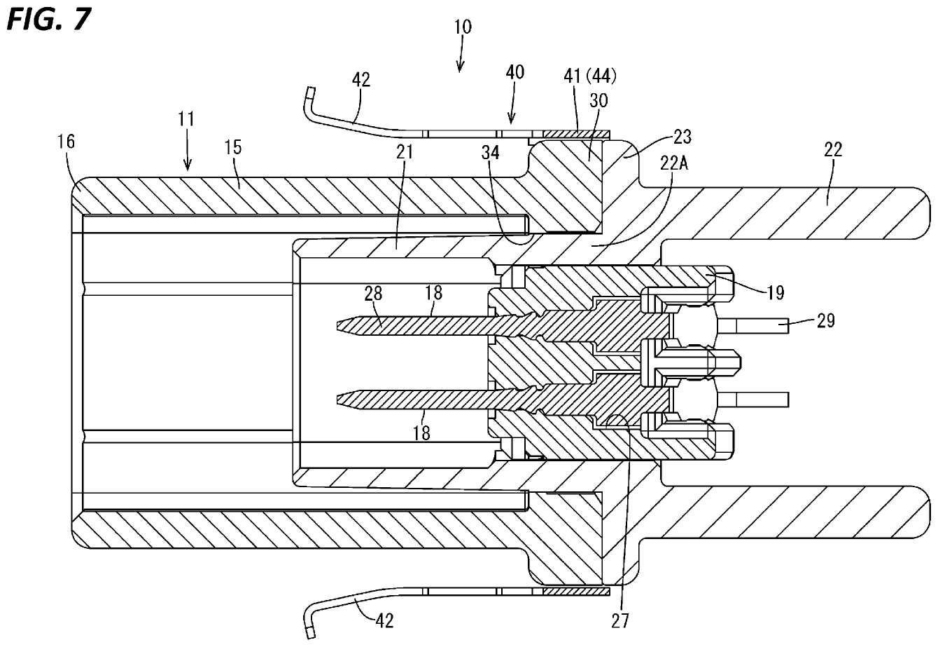

As shown in FIG. 2, the dielectric 19 is formed by injection-molding an insulating synthetic resin. The dielectric 19 is formed to have a substantially L-shaped cross-section. As shown in FIG. 7, the dielectric 19 includes inner conductor accommodation chambers 27 capable of accommodating the inner conductors 18 inside. The inner conductor accommodation chamber 27 is formed to penetrate through the dielectric 19 in the front-rear direction and also be open on a lower surface side.

### [Inner Conductors]

The inner conductor 18 is made of electrically conductive metal. An arbitrary metal such as copper, copper alloy, aluminum or aluminum alloy can be appropriately selected as a metal for constituting the inner conductor 18. The inner conductor 18 is formed by a known method such as press-working or cutting. The inner conductor 18 is electrically connected to a mating inner conductor (not shown) accommodated in the mating connector 70.

As shown in FIG. 2, the inner conductor 18 is formed by bending a tab-like metal plate halfway. The inner conductor 18 is formed into a step-like bent shape as a whole by being bent twice. The inner conductor 18 includes a terminal connecting portion 28 to be connected to the mating inner conductor (not shown) and a board connecting portion 29 to be connected to the inner conductor land 52 of the circuit board 50.

As shown in FIG. 6, the terminal connecting portion 28 is shaped to extend in the front-rear direction and projects further forward than the front end of the dielectric 19. On the other hand, the board connecting portion 29 is somewhat inclined as compared to the terminal connecting portion 28, and shaped to extend downward toward a rear side. Thus, the board connecting portion 29 is electrically connected to the signal electrically conductive path 53 of the circuit board 50 by being surface-mounted on the inner conductor land 52 by solder.

### [Ground Spring]

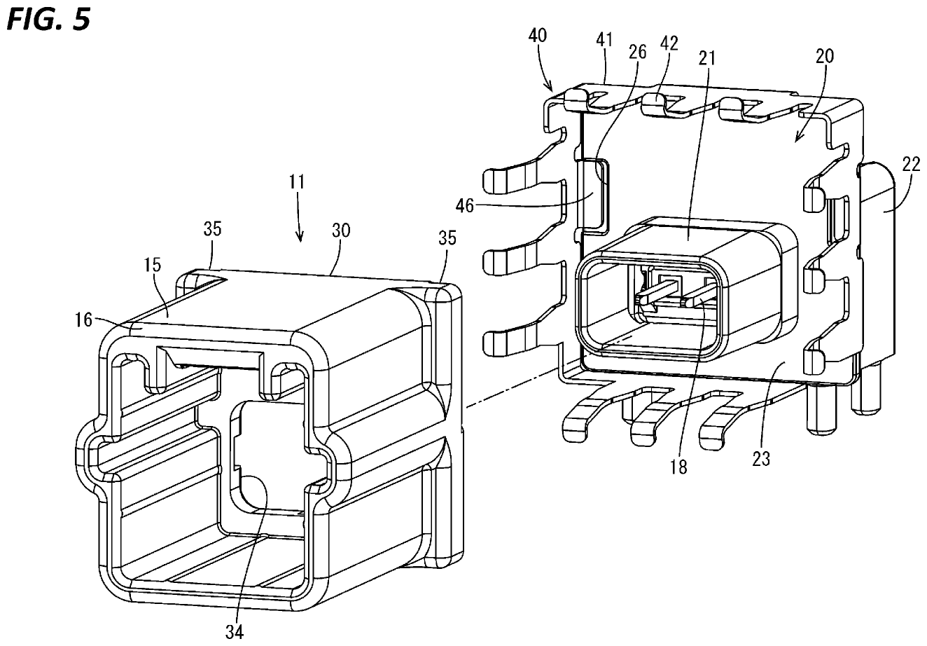

The ground spring 40 is made from an electrically conductive metal plate. An arbitrary metal such as copper, copper alloy, aluminum or aluminum alloy can be appropriately selected as a metal for constituting the ground spring 40. The ground spring 40 is formed by a known method such as press-working or cutting. As shown in FIG. 5, the ground spring 40 is already mounted on the outer conductor 20 in a state before the outer conductor 20 is attached to the housing 11 from behind.

As shown in FIG. 2, the ground spring 40 includes a gate-shaped mounting body portion 41 and a plurality of connection springs 42 projecting forward from the front edge of the mounting body portion 41. The mounting body portion 41 has a rectangular tube shape and includes a pair of side walls 44 arranged in parallel at a predetermined interval in the lateral direction, a ceiling wall 45 coupling the upper ends of the pair of side walls 44 and a bottom wall 47 extending from the lower end of the left side wall 44 to the lower end of the right side wall 44 in a front view.

The ceiling wall 45 corresponds to a “first mounting wall” described in claims, the bottom wall 47 corresponds to a “second mounting wall” described in claims and the side wall 44 corresponds to a “third mounting wall” described in claims.

A plurality of (three in this embodiment) the connection springs 42 are provided on each of outer surface sides of the ceiling wall 45, the pair of side walls 44 and the bottom wall 47. The connection spring 42 is cantilevered forward from the front edge of the mounting body portion 41. A front end part of the connection spring 42 is bent at a right angle, and can resiliently contact the front wall 66 of the enclosure 64 to be described later from behind.

Out of the plurality of connection springs 42, three connection springs 42 provided on the front edge of the ceiling wall 45 correspond to a “first enclosure connecting portion” described in claims. Out of the plurality of connection springs 42, nine connection springs 42 provided on the front edges of the pair of side walls 44 and the front edge of the bottom wall 47 correspond to a “second enclosure connecting portion” described in claims.

Further, each connection spring 42 disposed on an outer surface side of the first wall 15A corresponds to a “first connection spring” described in claims, and each of the connection springs 42 disposed on an outer surface side of the second wall 15B and outer surface sides of the pair of third walls 15C corresponds to a “second connection spring” described in claims.

A pair of clamping pieces 46 having a rectangular shape long in the vertical direction are provided to project inward on the rear edges of the pair of side walls 44. The left clamping piece 46 projects toward the right clamping piece 46 in a front view, and the right clamping piece 46 projects toward the left clamping piece 46 in the front view. The pair of clamping pieces 46 are arranged side by side in the lateral direction. The clamping piece 46 has a vertical dimension, which is equal to or less than half the vertical dimension of the side wall 44. The clamping piece 46 is provided at a position near the ceiling wall 45 on the side wall 44.

A holding spring 43 is provided on the rear edge of the ceiling wall 45. The holding spring 43 extends downward from a central part of the ceiling wall 45 and is formed into a chevron shape having a top on a front side. The holding spring 43 is flexible and in resilient contact with the rear surface of the flange 23 from behind in a state mounted on the outer conductor 20.

A pair of displacement suppressing portions 23A are provided at both left and right sides of the holding space 43 on the flange 23. The top of the holding spring 43 is fit between the pair of displacement suppressing portions 23A and both side edges of the holding spring 43 are laterally locked to the pair of displacement suppressing portions 23A, whereby the ground spring 40 can be held not to be displaced in the lateral direction with respect to the flange 23.

### [Mounting Structure of Ground Spring]

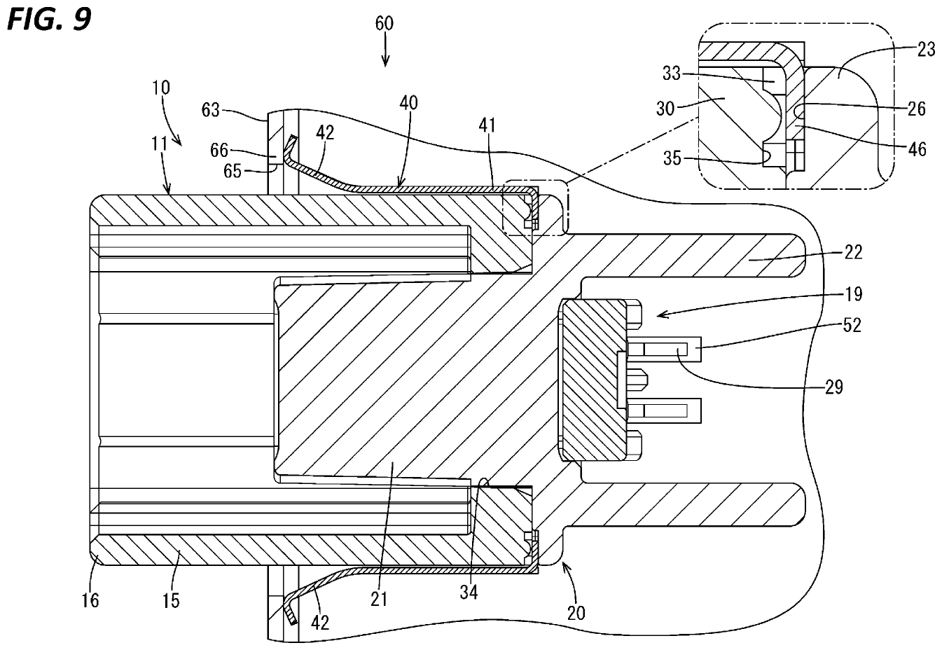

As shown in FIG. 5, a pair of mounting recesses 35 are provided on both left and right sides of the rear surface of the rear wall 30 of the housing 11. The mounting recess 35 is formed by recessing the rear surface of the rear wall 30 forward. As shown in FIG. 9, with the housing 11 and the outer conductor 20 assembled, mounting grooves 33 are formed by the mounting recesses 35 and the flange 23. The mounting groove 33 is located between the rear wall 30 and the flange 23 and is open upward and laterally. The mounting groove 33 located on a left side in a front view is open upward and leftward, and the mounting groove 33 located on a right side in the front view is open upward and rightward.

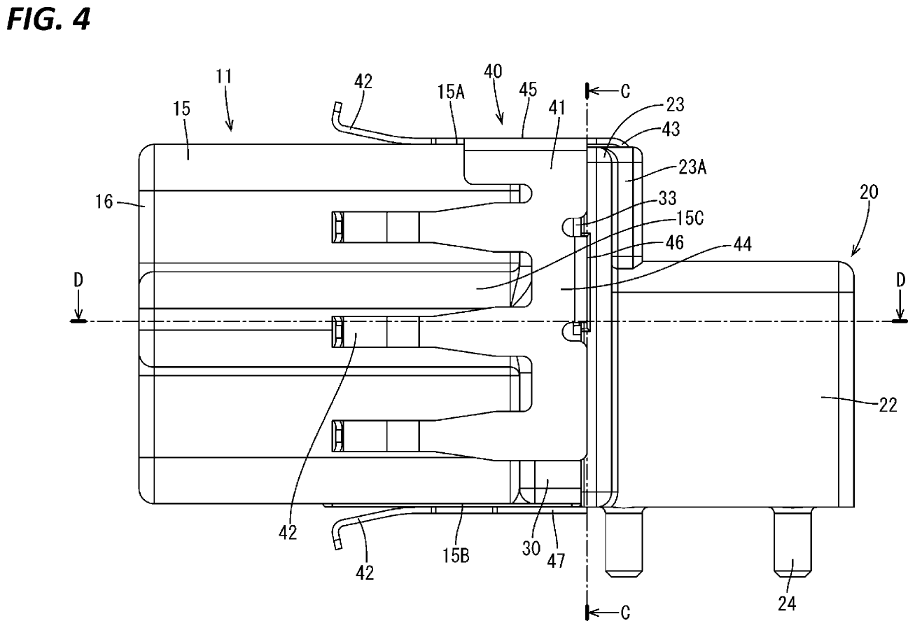

A dimension in the front-rear direction of the mounting groove 33 is equal to or somewhat larger than a plate thickness of the clamping piece 46. As shown in FIG. 4, a vertical dimension of the mounting groove 33 is about half the vertical dimension of the rear wall 30 and formed from the upper end to a vertical central part of the rear wall 30.

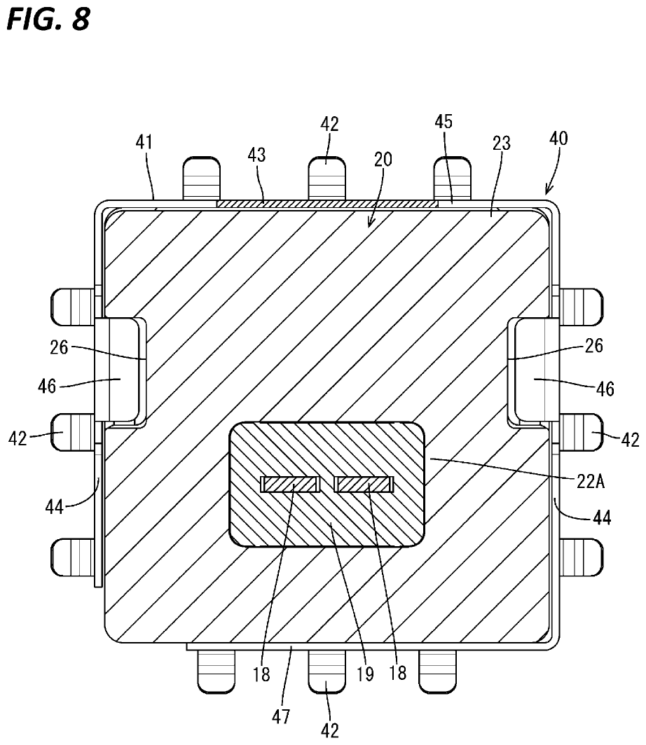

As shown in FIG. 6, with the ground spring 40 mounted on the flange 23, the holding spring 43 is in resilient contact with the flange 23 from behind, and the clamping pieces 46 are fit in the locking recesses 26 from front and resiliently contact the front surfaces of the locking recesses 26 as shown in FIG. 9. As shown in FIGS. 6 and 7, the mounting body portion 41 is disposed along the outer surface of the rear wall 30. As shown in FIG. 8, with the pair of clamping pieces 46 fit in the pair of locking recesses 26, the upper edges of the pair of clamping pieces 46 are locked to the upper edges of the pair of locking recesses 26 from below, whereby the ground spring 40 is held not to be detached upward.

### [Connection Structure of Ground Spring and Front Panel]

As shown in FIG. 10, the holding spring 43 is in resilient contact with the rear surface of the flange 23 and the connection springs 42 on both upper and lower sides are in resilient contact with the front wall 66 of the front panel 63. Further, as shown in FIG. 9, the pair of clamping pieces 46 are in resilient contact with the front surfaces of the pair of locking recesses 26 of the flange 23, and the connection springs 42 on both left and right sides are in resilient contact with the front wall 66 of the front panel 63. Since the ground spring 40 and the enclosure 64 are electrically connected at four upper, lower, left and right positions on an outer surface side of the receptacle 15 in this way, noise can be reduced. Further, since an electrically conductive path from the flange 23 to the front panel 63 is shortest, shielding performance can be improved.

A part of the front wall 66 in contact with the connection springs 42 on the upper side corresponds to a “first spring receiving portion” described in claims, and parts of the front wall 66 in contact with the connection springs 42 on the lower and both left and right sides correspond to a “second spring receiving portion” described in claims.

The electrically conductive path extending from the holding spring 43 of the ground spring 40 to the front wall 66 of the front panel 63 is branched into a plurality of parts by the plurality of connection springs 42 and the electrically conductive path extending from each clamping piece 46 to the front wall 66 of the front panel 63 is also branched into a plurality of parts by the plurality of connection springs 42. Since the ground spring 40 is connected to the front panel 63 at multiple contact points in this way, resistance at each contact point is reduced and shielding performance can be further improved.

### [Assembly Method of Board Connector and Device]

Next, an example of an assembly method of the board connector 10 and the device 60 of this embodiment is described. The assembly method of the board connector 10 and the device 60 is not limited to the one described below.

The inner conductors 18 are inserted into the inner conductor accommodation chambers 27 of the dielectric 19 from behind. Subsequently, the inner conductors 18 are assembled with the outer conductor 20 from behind. In this way, a part of the dielectric 19 extending in the front-rear direction is press-fit into the dielectric holding portion 22A of the outer conductor 20 and the dielectric 19 is held retained. In this state, the terminal connecting portions 28 of the inner conductors 18 are accommodated inside the tube portion 21 (see FIG. 7).

Subsequently, if the ground spring 40 is mounted on the flange 23, the holding spring 43 resiliently contacts the flange 23 from behind and the pair of clamping pieces 46 resiliently contact the pair of locking recesses 26 from front. In this way, the ground spring 40 is electrically connected to the outer conductor 20 at a plurality of positions (three positions in this embodiment).

Subsequently, the tube portion 21 of the outer conductor 20 is inserted into the outer conductor mounting hole 34 of the housing 11 from behind and the dielectric holding portion 22A is press-fit into the outer conductor mounting hole 34. In this way, the board connector 10 is completed and the flange 23 is disposed along the rear wall 30 of the housing 11.

Subsequently, the board connector 10 is assembled with the circuit board 50 from above. The board connecting portions 24 of the outer conductor 20 are inserted into the outer conductor through holes 51 of the circuit board 50 from above, and the board connecting portions 29 of the inner conductors 18 are placed on the inner conductor lands 52 of the circuit board 50 from above and soldered, whereby the board connecting portions 29 and the inner conductor lands 52 are electrically connected.

Subsequently, the circuit board 50 is fixed to the lower case 61, such as by screwing. The upper case 62 is assembled from above the lower case 61, the front panel 63 is assembled from the front of the lower case 61, and the lower case 61, the upper case 62 and the front panel 63 are fixed, such as by screwing. In this way, the enclosure 64 is configured and the board connector 10 and the circuit board 50 are accommodated inside the enclosure 64 with the receptacle 15 passed through the connector insertion hole 65.

At this time, front end parts of the plurality of connection springs 42 are pressed against and brought into resilient contact with the front wall 66 of the front panel 63 from behind. In this way, the ground spring 40 is electrically connected to the enclosure 64 at multiple contact points. Accordingly, the outer conductor 20 is shield-connected to the enclosure 64 via the ground spring 40. Apart from this, the outer conductor 20 is shield-connected to the enclosure 64 via the plurality of board connecting portions 24 and the circuit board 50, but a distance to the enclosure 64 can be short and the ground spring 40 resiliently contacts the enclosure 64 with shield connection by the ground spring 40. Thus, a connected state is stable and shielding performance can be improved. That is, since the flange 23 is clamped by the holding spring 43 and the clamping pieces 46, a sufficient contact pressure can be secured and stable shield connection is possible.

Subsequently, the board connector 10 and the mating connector 70 are connected. If the mating connector 70 is fit into the receptacle 15, the lock arm (not shown) provided on the mating connector 70 is locked to the lock portion 31. In this way, the mating connector 70 is held retained in the housing 11. The inner conductors 18 of the board connector 10 are electrically connected to the mating inner conductors (not shown) of the mating connector 70. Further, the outer conductor 20 of the board connector 10 is electrically connected to the mating outer conductor (not shown) of the mating connector 70.

### [Functions and Effects of First Embodiment]

The board connector 10 of the present disclosure is to be mounted on the circuit board 50 and provided with the housing 11 including the receptacle 15 open forward and the rear wall 30 provided on the side opposite to the front end part 16 where the receptacle 15 is open, the outer conductor 20 fixed to the housing 11 through the rear wall 30, the insulating dielectric 19 disposed inside the outer conductor 20, the inner conductors 18 disposed inside the dielectric 19 and the ground spring 40 to be connected to the outer conductor 20. The receptacle 15 includes the first wall 15A to be disposed on the side opposite to the circuit board 50, the second wall 15B to be disposed on the side of the circuit board 50, and the third walls 15C coupling the first and second walls 15A, 15B. The ground spring 40 includes the first enclosure connecting portion disposed on the outer surface side of the first wall 15A, and the second enclosure connecting portions disposed on the outer surface sides of both the second wall 15B and the third walls 15C.

The device 60 of the present disclosure is provided with the board connector 10, the circuit board 50 having the board connector 10 mounted thereon, and the enclosure 64 made of metal, configured to accommodate the circuit board 50 inside and electrically connected to the outer conductor 20 via the ground spring 40. The enclosure 64 includes the first spring receiving portion to be connected to the first enclosure connecting portion and the second spring receiving portions to be connected to the second enclosure connecting portions.

Since the ground spring 40 includes the first and second enclosure connecting portions, the ground spring 40 can be shield-connected to the enclosure 64 at least at two positions, and noise can be reduced. Further, since the outer conductor 20 and the enclosure 64 made of metal can be electrically connected via the ground spring 40, the connected state is stable and shielding performance can be improved.

The ground spring 40 includes the mounting body portion 41 to be disposed along the outer surface of the rear wall 30, the first enclosure connecting portion includes a plurality of first connection springs projecting forward from the front edge of the mounting body portion 41, and the second enclosure connecting portion includes a plurality of second connection springs projecting forward from the front edge of the mounting body portion 41.

Since the ground spring 40 includes the plurality of first connection springs and the plurality of second connection springs, the ground spring 40 can be shield-connected to the enclosure 64 at multiple contact points and shielding performance can be further improved.

The mounting body portion 41 has a rectangular tube shape and includes the ceiling wall 45 corresponding to the first wall 15A, the bottom wall 47 corresponding to the second wall 15B and the side walls 44 corresponding to the third walls 15C, the pair of side walls 44 are provided to face each other in a direction orthogonal to a facing direction of the ceiling wall 45 and the bottom wall 47, and the second enclosure connecting portions are disposed on both the bottom wall 47 and the pair of side walls 44. Since the ground spring includes one first enclosure connecting portion and three second enclosure connecting portions, the ground spring can be shield-connected to the enclosure at least at four positions and noise can be further reduced.

The outer conductor 20 includes the flange 23 to be disposed along the rear wall 30 of the housing 11, the ceiling wall 45 includes the holding spring 43 to be brought into resilient contact with the flange 23 from behind, and the pair of side walls 44 include the pair of clamping pieces 46 for clamping the flange 23 together with the holding spring 43.

Since the flange 23 can be clamped by the holding spring 43 and the pair of clamping pieces 46, the connected state of the ground spring 40 to the flange 23 is stable.

A pair of the second enclosure connecting portions are provided on the pair of side walls 44, the holding spring 43 is provided on the rear edge of the ceiling wall 45, and the pair of clamping pieces 46 are provided on the rear edges of the pair of side walls 44.

Since the holding spring 43 is provided on the rear edge of the ceiling wall 45, the holding spring 43 and the first enclosure connecting portion can be connected by a shortest distance. Further, since the pair of clamping pieces 46 are provided on the rear edges of the pair of side walls 44, the pair of clamping pieces 46 and the pair of second enclosure connecting portions can be connected by a shortest distance.

### Details of Second Embodiment of Present Disclosure

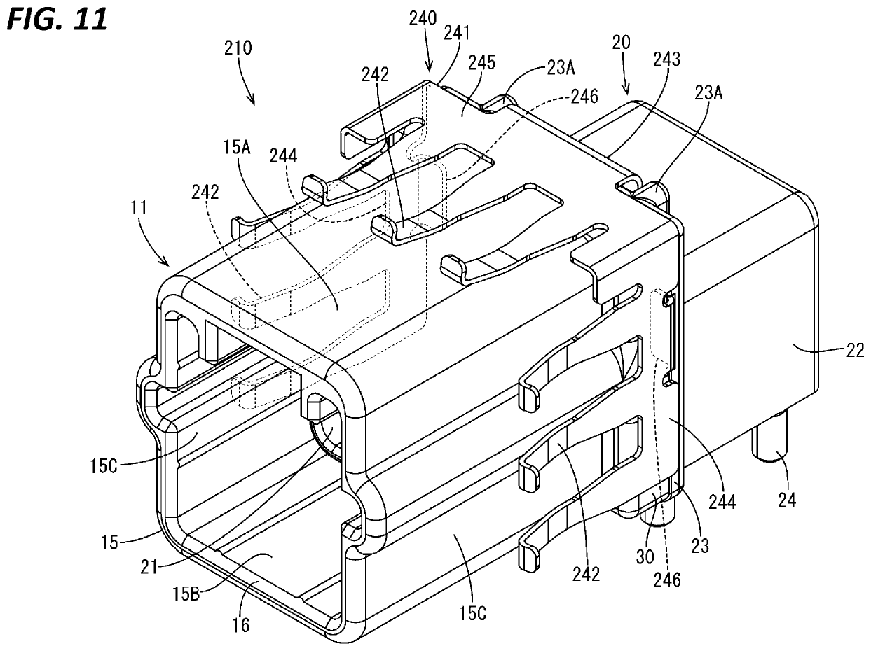

A specific example of a board connector 210 of the present disclosure is described with reference to FIG. 11. In the following description, the same components as in the first embodiment are not described and reference sings obtained by adding 200 to numeric parts of the reference signs are used for components corresponding to those of the first embodiment.

### [Overall Structures of Board Connector and Device]

As shown in FIG. 11, the board connector 210 differs from the board connector 10 of the first embodiment in that a ground spring 240 can be retrofit from above to the board connector 210 having the ground spring 240 not mounted thereon yet.

### [Board Connector]

The board connector 210 includes a housing 11 to be mounted on a circuit board 50, an outer conductor 20 to be attached to the housing 11, a dielectric 19 to be accommodated inside the outer conductor 20, inner conductors 18 to be accommodated inside the dielectric 19 and the ground spring 240 to be connected to the outer conductor 20.

### [Ground Spring]

The ground spring 240 can be retrofit to the outer conductor 20. Retrofitting means that the ground spring 240 can be mounted on the outer conductor 20 after the board connector 210 having the ground spring 240 not mounted thereon yet is mounted on the circuit board 50.

The ground spring 240 includes a gate-shaped mounting body portion 241 and a plurality of connection springs 242 projecting forward from the front edge of the mounting body portion 241. The mounting body portion 241 includes a pair of side walls 244 arranged in parallel at a predetermined interval in the lateral direction and a ceiling wall 245 coupling the upper ends of the pair of side walls 244. The ground spring 240 of this embodiment includes no part corresponding to the bottom wall 47 and does not have a rectangular tube shape unlike the ground spring 40 of the first embodiment.

A plurality of (three in this embodiment) the connection springs 242 are provided on each of the ceiling wall 245 and the pair of side walls 244.

A pair of clamping pieces 246 having a rectangular shape long in the vertical direction are provided to project inward on the rear edges of the pair of side walls 244. One clamping piece 246 projects toward the other clamping piece 246, and the other clamping piece 246 projects toward the one clamping piece 246. The pair of clamping pieces 246 are arranged side by side in the lateral direction.

A holding spring 243 is provided on the rear edge of the ceiling wall 245. The holding spring 243 extends downward (in a mounting direction on the board connector 210) from a central part of the ceiling wall 245 and is formed into a chevron shape having a top on a front side. The holding spring 243 is flexible and in resilient contact with the rear surface of a flange 23 from behind in a state mounted on the outer conductor 20.

### [Mounting Structure of Ground Spring]

If the ground spring 240 is assembled from above with the board connector 210 having the ground spring 240 not mounted thereon yet, the pair of clamping pieces 246 are respectively inserted into a pair of mounting grooves 33. When the ground spring 240 reaches a proper mounting position, the holding spring 243 resiliently contacts the flange 23 from behind and the clamping pieces 246 resiliently contact locking recesses 26. With the top of the holding spring 243 fit between a pair of displacement suppressing portions 23A, both side edges of the holding spring 243 are laterally locked to the pair of displacement suppressing portions 23A, whereby the ground spring 240 is held not be displaced in the lateral direction.

### [Connection Structure of Ground Spring and Front Panel]

The holding spring 243 is in resilient contact with the rear surface of the flange 23 and the connection springs 242 on an upper and both left and right sides are in resilient contact with a front wall 66 of a front panel 63. Thus, an electrically conductive path from the flange 23 to the front panel 63 is shortest, wherefore shielding performance can be improved.

Electrically conductive paths from the holding spring 243 and the respective clamping pieces 246 to the front wall 66 of the front panel 63 are branched into a plurality of parts by the plurality of connection springs 242. Since the ground spring 240 is connected to the front panel 63 at multiple contact points in this way, resistance at each contact point is reduced and shielding performance can be further improved.

### [Mounting Method of Ground Spring]

The ground spring 240 is mounted on the board connector 210. The ground spring 240 is mounted laterally on the board connector 210, and the pair of clamping pieces 246 are inserted into the pair of mounting grooves 33 from above. When the ground spring 240 reaches the proper mounting position, the holding spring 243 resiliently contacts the flange 23 from behind and the pair of clamping pieces 246 resiliently contact the front surfaces of the pair of locking recesses 26 from front. In this way, the ground spring 240 is electrically connected to the outer conductor 20 at a plurality of positions (three positions in this embodiment).

Subsequently, the circuit board 50 is fixed to a lower case 61, such as by screwing. An upper case 62 is assembled from above the lower case 61, the front panel 63 is assembled from the front of the lower case 61, and the lower case 61, the upper case 62 and the front panel 63 are fixed, such as by screwing. In this way, an enclosure 64 is configured and the board connector 210 and the circuit board 50 are accommodated inside the enclosure 64 with a receptacle 15 passed through a connector insertion hole 65.

At this time, front end parts of the plurality of connection springs 242 are pressed against and brought into resilient contact with the front wall 66 of the front panel 63 from behind. In this way, the ground spring 240 is electrically connected to the enclosure 64 at multiple contact points. Accordingly, the outer conductor 20 is shield-connected to the enclosure 64 via the ground spring 240. Apart from this, the outer conductor 20 is shield-connected to the enclosure 64 via a plurality of board connecting portions 24 and the circuit board 50, but a distance to the enclosure 64 can be short and the ground spring 240 resiliently contacts the enclosure 64 with shield connection by the ground spring 240. Thus, a connected state is stable and shielding performance can be improved. That is, since the flange 23 is clamped by the holding spring 243 and the clamping pieces 246, a sufficient contact pressure can be secured and stable shield connection is possible.

### [Functions and Effects of Second Embodiment]

According to the board connector 210 of the second embodiment, since the ground spring 240 is gate-shaped, the ground spring 240 can be retrofit to the outer conductor 20.

### Details of Third Embodiment of Present Disclosure

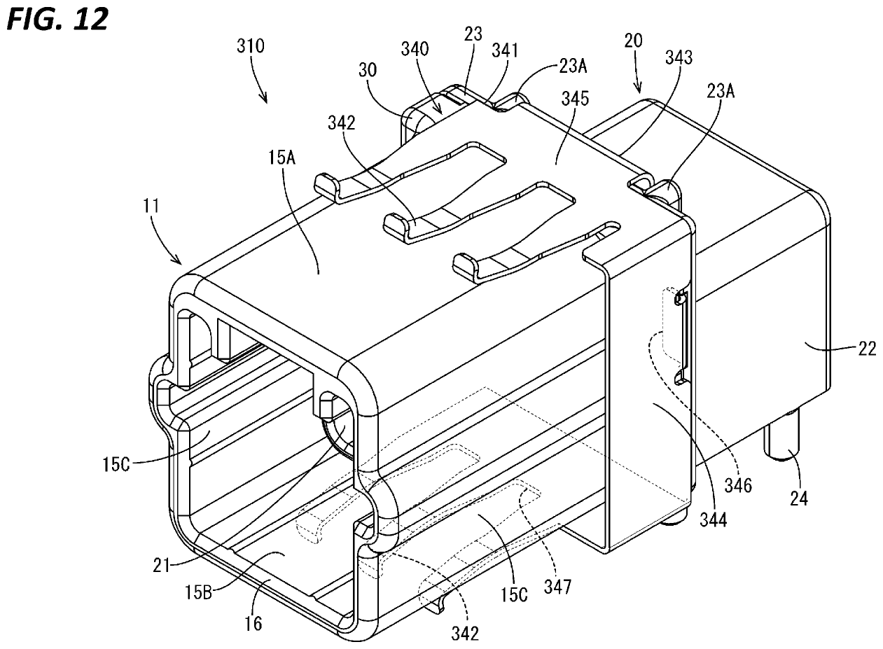

A specific example of a board connector 310 of the present disclosure is described with reference to FIG. 12. In the following description, the same components as in the first embodiment are not described and reference sings obtained by adding 300 to numeric parts of the reference signs are used for components corresponding to those of the first embodiment.

### [Board Connector]

The board connector 310 includes a housing 11 to be mounted on a circuit board 50, an outer conductor 20 to be attached to the housing 11, a dielectric 19 to be accommodated inside the outer conductor 20, inner conductors 18 to be accommodated inside the dielectric 19 and a ground spring 340 to be connected to the outer conductor 20.

### [Ground Spring]

The ground spring 340 includes a gate-shaped mounting body portion 341 and a plurality of connection springs 342 projecting forward from the front edge of the mounting body portion 341. The mounting body portion 341 includes a ceiling wall 345 and a bottom wall 347 arranged in parallel at a predetermined interval in the vertical direction and a side wall 344 coupling the right ends of these ceiling wall 345 and bottom wall 347. The ground spring 340 of this embodiment includes no part corresponding to the left side wall 44 and does not have a rectangular tube shape unlike the ground spring 40 of the first embodiment.

### Other Embodiments

(1) Although the connection springs 42 are provided on at least two or more of the second wall 15B and the pair of third walls 15C in the first to third embodiments, the connection springs may be provided on only one of the second wall 15B and the pair of third walls 15C. For example, the connection springs 42 may be provided on only the first wall 15A and the second wall 15B or may be provided on only the first wall 15A and one third wall 15C.

(2) Although the pair of displacement suppressing portions 23A are provided on the rear surface of the flange 23 in the first to third embodiments, a locking recess may be provided in the rear surface of the flange in addition to the pair of displacement suppressing portions 23A and the top of the holding spring may be fit into this locking recess. By doing so, the holding spring is less likely to be detached from the flange.

(3) Although three connection springs are provided on the front edge of each mounting wall in the first to third embodiments, only one, two, four or more connection springs may be provided.

(4) Although the ground spring is integrally configured in the first to third embodiments, a ground spring may be composed of a pair of half bodies.

(5) One, three or more inner conductors 18 may be provided.

(6) The outer conductor may be formed by press-working a metal plate material.

(7) Although the housing and the outer conductor are fixed by press-fitting, these may be fixed by thermal caulking.

### LIST OF REFERENCE NUMERALS

10: board connector, 11: housing, 15: receptacle, 15A: first wall, 15B: second wall, 15C: third wall, 16: front end part, 18: inner conductor, 19: dielectric, 20: outer conductor, 21: tube portion, 22: dielectric surrounding portion, 22A: dielectric holding portion, 23: flange, 23A: displacement suppressing portion, 24: board connecting portion, 26: locking recess, 27: inner conductor accommodation chamber, 28: terminal connecting portion, 29: board connecting portion
30: rear wall, 31: lock portion, 32: mold removal hole, 33: mounting groove, 34: outer conductor mounting hole, 35: mounting recess
40: ground spring, 41: mounting body portion, 42: connection spring (first connection spring, second connection spring), 43: holding spring, 44: side wall (third mounting wall), 45: ceiling wall (first mounting wall), 46: clamping piece, 47: bottom wall (second mounting wall)
50: circuit board, 51: outer conductor through hole, 52: inner conductor land, 53: signal electrically conductive path, 54: ground electrically conductive path
60: device, 61: lower case, 62: upper case, 63: front panel, 64: enclosure, 65: connector insertion hole, 66: front wall (first spring receiving portion, second spring receiving portion)
70: mating connector
210: board connector
240: ground spring, 241: mounting body portion, 242: connection spring, 243: holding spring, 244: side wall (third mounting wall), 245: ceiling wall (first mounting wall), 246: clamping piece
310: board connector
340: ground spring, 341: mounting body portion, 342: connection spring, 343: holding spring, 344: side wall (third mounting wall), 345: ceiling wall (first mounting wall), 346: clamping piece, 347: bottom wall (second mounting wall)

1. A board connector to be mounted on a circuit board, comprising:
a housing including a receptacle open forward and a rear wall provided on a side opposite to a front end part where the receptacle is open;
an outer conductor fixed to the housing through the rear wall;
an insulating dielectric disposed inside the outer conductor;
an inner conductor disposed inside the dielectric; and
a ground spring to be connected to the outer conductor,
the receptacle including a first wall to be disposed on a side opposite to the circuit board, a second wall to be disposed on the circuit board side and a third wall coupling the first wall and the second wall, and
the ground spring including a first enclosure connecting portion disposed on an outer surface side of the first wall and a second enclosure connecting portion disposed on an outer surface side of each or either one of the second wall and the third wall.

2. The board connector of claim 1, wherein the ground spring includes a mounting body portion to be disposed along an outer surface of the rear wall, the first enclosure connecting portion includes a plurality of first connection springs projecting forward from a front edge of the mounting body portion, and the second enclosure connecting portion includes a plurality of second connection springs projecting forward from the front edge of the mounting body portion.

3. The board connector of claim 2, wherein the mounting body portion has a rectangular tube shape and includes a first mounting wall corresponding to the first wall, a second mounting wall corresponding to the second wall and third mounting walls corresponding to the third wall, a pair of the third mounting walls are provided to face each other in a direction orthogonal to a facing direction of the first mounting wall and the second mounting wall, and the second enclosure connecting portions are disposed on both the second mounting wall and the pair of third mounting walls.

4. The board connector of claim 3, wherein:
the outer conductor includes a flange to be disposed along the rear wall of the housing, and
the first mounting wall includes a holding spring to be brought into resilient contact with the flange from behind and the pair of third mounting walls include a pair of clamping pieces for clamping the flange together with the holding spring.

5. The board connector of claim 4, wherein:
a pair of the second enclosure connecting portions are provided on the pair of third mounting walls, and
the holding spring is provided on a rear edge of the first mounting wall and the pair of clamping pieces are provided on rear edges of the pair of third mounting walls.

6. A device, comprising:
the board connector of claim 1;
a circuit board having the board connector mounted thereon; and
an enclosure made of metal, the circuit board being accommodated inside the enclosure, the enclosure being electrically connected to the outer conductor via the ground spring,
the enclosure including a first spring receiving portion to be connected to the first enclosure connecting portion and a second spring receiving portion to be connected to the second enclosure connecting portion.
